(19) United States
(12) Patent Application Publication
(10) Pub. No.: US 2013/0037419 A1
(43) Pub. Date: Feb. 14, 2013

(54) ELECTROMECHANICAL SYSTEMS INCLUDING BIOCHEMICAL ACTUATOR HEADS

(71) Applicants: Kevin Kit Parker, Waltham, MA (US); Megan O'Grady, Dallas, TX (US)

(72) Inventors: Kevin Kit Parker, Waltham, MA (US); Megan O'Grady, Dallas, TX (US)

(73) Assignee: PRESIDENT AND FELLOWS OF HARVARD COLLEGE, Cambridge, MA (US)

(21) Appl. No.: 13/579,697

(22) PCT Filed: Feb. 18, 2011
(86) PCT No.: PCT/US11/25420

§ 371 Date: Oct. 22, 2012

Related U.S. Application Data
(60) Provisional application No. 61/306,167, filed on Feb. 19, 2010.

(51) Int. Cl. G01N 27/327; H01L 21/02; B01D 43/00; G01N 27/417; G01N 27/406

(52) U.S. Cl. 205/766; 204/403.01; 204/242; 205/792; 205/777.5; 438/49; 257/E21.002

(57) ABSTRACT

Disclosed herein are biochemical actuator heads instrumented with a receptor conductive polymer for reversibly controlling ligand-receptor interactions. Also disclosed are systems and methods for utilizing and fabricating the biochemical actuator head. The biochemical actuator head and related systems and methods may be used in a wide array of applications including, without limitation, micro/nano assembly, examination of cellular signaling mechanisms, image-guided cell nanosurgery or particle processing. Particle processing systems and methods are also provided utilizing a receptor conductive polymer for reversibly controlling ligand-receptor interactions.

### RELATED APPLICATIONS

This application claims priority to U.S. Provisional Application No. 61/306,167, filed on Feb. 19, 2010, the entire contents of which are incorporated herein by this reference.

### GOVERNMENT SUPPORT

This invention was supported, at least in part, by NFS Grant DMR-0820484. The US government may have certain rights to this invention.

### BACKGROUND

The present disclosure relates to the field of nanotechnology. More particularly the present disclosure relates to microelectromechanical systems (MEMS) and nanoelectromechanical systems (NEMS) and associated methods of use and manufacture. An emerging trend in biotechnology and medical diagnostics is to improve the speed and sensitivity of molecular analyses via label-free, noninvasive techniques that exploit electrochemical and microelectronic technologies. Label-free detection methods have been widely utilized to monitor analyte concentrations, most commonly using ion-sensitive semiconductor field effect transistors (ISFETs) or conductive polymeric devices. These label-free technologies are scalable, with the added advantage that they can be used to quantitatively measure a variety of molecular concentration gradients in a highly parallel fashion via surface modifications of individual sensors.

Although the biocompatibility and high-throughput of label-free technologies are favorable, existing devices are limited in that they do not allow investigators to actively control molecular binding at the sensor surface. Consequently, conventional label-free devices cannot be used to mediate adsorption of biomolecules to a functionalized surface in an on-off fashion. Nor can conventional label-free devices be used to dynamically detect molecular gradients within cell or tissue microenvironments. Thus, despite efforts to date a need exists for systems and methods that would enable actuation of biochemical interactions on a microscale and nanoscale level. Such systems and methods would advantageously allow label-free technologies to move well beyond the analyte sensor applications currently realized.

Flow cytometry advantageously enables highly sensitive counting and sorting of particles, such as cells and chromosomes. Yet, commercially available flow cytometers are expensive, mechanically complex, and require specialists to operate. Conventional microfluidic flow cytometers often enable recovery of particles of interest, however do not achieve the incredible sensitivity of adhesion-based cell separation (for example, the separation of cancer cells from a blood sample). Moreover, conventional microfluidic flow cytometers typically do not have the capability to deal with the fluid complexity of large volumes of whole blood samples. Thus, despite efforts to date a need exists for detachable adhesion-based sorting.

These and other needs are satisfied by the systems and methods of the present disclosure.

### SUMMARY

A biochemical actuator head instrumented with a receptor doped conductive polymer (e.g., polypyrrole) is provided according to the present disclosure for reversibly controlling ligand-receptor interactions. Systems and methods for utilizing and fabricating the biochemical actuator head are also provided according to the present disclosure.

In one aspect of the invention, an electromechanical system comprising a biochemical actuator head is disclosed generally including a tip functionalized with, e.g., formed, coated, or otherwise operatively associated with, a receptor doped electroactive polymer, whereby the biochemical actuator head is able to selectively and reversible modulate affinity with respect to ligand-receptor interactions at the tip in response to changes in electric potential across the polymer.

In one embodiment, an electromechanical system is disclosed generally including the biochemical actuator head and an actuator, for example, a piezoelectric actuator operatively coupled relative to the biochemical actuator for selectively positioning the biochemical actuator head.

In one embodiment, the electroactive polymer is polypyrole (PPy).

In one embodiment, the receptor is an antibody and the ligand is an antigen.

In one embodiment, a positive potential induces binding of the antibody at the tip to a negatively charged antigen. In another embodiment, a negative potential inhibits binding of the antibody at the tip to a negatively charged antigen.

In one embodiment, the electroactive polymer is doped with an antibody for fibronectin (αFN).

In one embodiment, the biochemical actuator head is a modified atomic force microscopy (AFM) probe.

In one embodiment, the biochemical actuator head is roughly conical. In one embodiment, the biochemical actuator head is operatively coupled relative to the piezoelectric actuator by means of a cantilever.

In one embodiment, the electromechanical system of further comprises an array of biochemical actuator heads operatively coupled relative to the actuator.

In one embodiment, the electromechanical system is one of a nanoelectromechanical system (NEMS) and a microelectromechanical system (MEMS).

In one embodiment, the electromechanical system further comprises a processor adapted the control algorithm applies characterizations of ligand-receptor interactions as functions of one or more of: applied potential, binding and release kinetics, and concentration. In one embodiment, the processor is adapted to determine flux at the tip using the Nernst-Planck equation. In one embodiment, the processor is further adapted to characterize binding and release as a function of binding and release kinetics and the flux. In one embodiment, the processor is further adapted to characterize ligand-receptor interactions away from the tip using a diffusion-reaction model.

In one embodiment, the electromechanical system, further comprises an imaging system for real-time quality control and quantitative analysis of ligand-receptor interactions at the tip. In one embodiment, the imaging system includes an inverted optical microscope coupled to a CCD camera. In one embodiment, the imaging system is adapted to determine the location of a ligand and position the biochemical actuator head proximate thereto.

In one embodiment, the actuator is a piezoelectric actuator.

In another aspect, a method for selectively and reversibly controlling ligand-receptor interactions using an elecromechanical system including a biochemical actuator head is disclosed generally including steps of applying a first electric potential across the polymer to facilitate binding of a ligand at the tip and applying a second electric potential across the polymer to facilitate releasing the ligand from the biochemical actuator head.

In one embodiment, the invention provides methods for selectively and reversibly controlling ligand-receptor interactions using an elecromechanical system including a biochemical actuator head having a tip functionalized with a receptor doped electroactive polymer, whereby the biochemical actuator head is able to selectively and reversibly modulate affinity with respect to ligand-receptor interactions at the tip in response to changes in electric potential across the polymer. The methods include applying a first electric potential across the polymer to facilitate binding of a ligand at the tip; and applying a second electric potential across the polymer to facilitate releasing the ligand from the biochemical actuator head.

In one embodiment, the electroactive polymer is polypyrole (PPy).

In one embodiment,the ligand is an antigen and wherein the receptor electroactive polymer is doped with an antibody for the antigen. In one embodiment, the antigen is fibronectin (FN) and wherein the antibody is an antibody for fibronectin (αFN). In one embodiment, the ligand is associated with a cellular structure.

In one embodiment, the binding and releasing of the ligand is used to investigate cell signaling mechanisms. In one embodiment, the binding and releasing of the ligand is used to examine cell responses to biochemical stimulation.

In one embodiment, the ligand is associated with a ferromagnet bead and wherein the method is used to reversibly flip the domain thereof.

In one embodiment, the methods further comprise using an actuator operatively coupled relative to the biochemical actuator head to selectively position the ligand prior to releasing. In one embodiment, the actuator is a piezoelectric actuator. In one embodiment, the ligand is associated with a cellular structure and wherein the method is used to perform cell nanosurgery. In one embodiment, the ligand is associated with a nanostructure and wherein the method is repeated to build a nanodevice.

In one embodiment, the methods further comprise initial steps of using an imaging system to determine the location of the ligand and using an actuator operatively coupled relative to the biochemical actuator to position the biochemical actuator head proximate to the ligand.

In one embodiment, the actuator is a piezoelectric actuator.

In one embodiment, the determining the location of the ligand includes using a generalized second derivative test to detect relative intensity maxima within a confocal fluorescence image.

In one embodiment, the methods further comprise the initial steps of using a thresholding approach to determine an upper boundary (TUB) grayscale value and a lower boundary (TLB) grayscale value; binarizing the image with increasing threshold values to generate a curve composed of the average area of thresholded regions as a function of threshold value; and determining an optimal threshold as the maximum threshold value in the range of TLB to TUB, wherein each thresholded region is analyzed for the presence of potential beads using a generalized second derivative test to detect maxima. In one embodiment, the methods, further include an initial step of applying a top-hat filter to the image. In one embodiment, the methods further include determining actual maxima, wherein a relative maximum region not having a corresponding actual maximum is discarded and wherein a relative maximum region having two or more actual maxima is split using marker-controlled watershed segmentation. In one embodiment, after determining the actual maxima, a filtering step is used to identify and remove low intensity actual maxima.

In another aspect, the invention provides a biochemical actuator head comprising a tip functionalized with a receptor doped electroactive polymer, wherein the biochemical actuator head is adapted to selectively and reversible modulate affinity with respect to ligand-receptor interactions at the tip in response to changes in electrical potential across the polymer.

In one embodiment, the electroactive polymer is polypyrole (PPy).

In one embodiment, the receptor is an antibody and the ligand is an antigen.

In one embodiment, a positive potential induces binding of the antibody at the tip to the negatively charged antigen. In another embodiment, a negative potential inhibits binding of the antibody at the tip to the negatively charged antigen.

In one embodiment, the receptor polymer is doped with an antibody for fibronectin (αFN).

In one embodiment, the biochemical actuator head is a modified atomic force microscopy (AFM) probe.

In one embodiment, the biochemical actuator head is roughly conical.

In one embodiment, the biochemical actuator head is associated with or integral with a cantilever.

In another aspect, a method for manufacture of the biochemical actuator head is disclosed generally including depositing a first metal adhesion layer on silicon head, depositing an electrode layer on top of the first metal adhesion layer, depositing a second adhesion layer on top of the electrode layer, depositing an amorphous silicon on top of the second adhesion layer, exposing the underlying electrode layer at the tip of the head using a focused ion beam, and electropolymerizing a receptor doped electroactive polymer on the exposed electrode surface.

In another aspect, the invention provides a method for manufacture of the biochemical actuator head is disclosed generally including depositing a first metal adhesion layer on silicon head, depositing an electrode layer on top of the first metal adhesion layer, depositing a second adhesion layer on top of the electrode layer, depositing an amorphous silicon on top of the second adhesion layer, exposing the underlying electrode layer at the tip of the head using a focused ion beam, and electropolymerizing a receptor doped electroactive polymer on the exposed electrode surface.

In one embodiment, the silicon head is initially flattened using a focused ion beam.

In one embodiment, each of the first and second adhesion layers is chromium or titanium.

In one embodiment, the electrode layer is gold.

In one embodiment, a physical vapor deposition instrument is used to deposit each of the first and second adhesion layers and the electrode layer.

In one embodiment, wherein a plasma enhanced chemical vapor deposition instrument is used to deposit the amorphous-silicon layer.

In one embodiment, exposing the underlying electrode layer at the tip is achieved using a dual-beam instrument featuring both etching and scanning electron microscope (SEM) capabilities, wherein the SEM capabilities are used for focusing purposes prior to etching.

The biochemical actuator head and related systems and methods may be used in a wide array of applications including, without limitation, micro/nano assembly, examination of cellular signaling mechanisms, image-guided cell nanosurgery, particle processing (for example, particle analysis, manipulation, sorting, assaying, and the like) and other related or similar applications.

In an exemplary aspect, a particle processing system is disclosed at least a portion of which is functionalized with a receptor doped electroactive polymer whereby the particle processing system is adapted to selectively and reversible modulate affinity with respect to ligand-receptor interactions at the functionalized portion in response to changes in electrical potential across the polymer.

In one embodiment, the invention provides a particle processing system at least a portion of which is functionalized with a receptor doped electroactive polymer whereby the particle processing system is adapted to selectively and reversible modulate affinity with respect to ligand-receptor interactions at the functionalized portion in response to changes in electrical potential across the polymer.

In one embodiment, the particle processing system is a microfluidic system.

In one embodiment, the functionalized portion is a tip of a biochemical actuator head included in the particle processing system.

In one embodiment, the particle processing system further includes an actuator operatively coupled relative to the biochemical actuator head for selectively positioning the biochemical actuator head within the particle processing system.

In one embodiment, the functionalized portion is at least a portion of a channel included in the particle processing system.

In one embodiment, the modulation of affinity with respect to ligand-receptor interactions at the functionalized portion is used to reversibly bind ligand-labeled particles flowing through the channel.

In one embodiment, the particle processing system is adapted to provide a particle flow, wherein the particle flow is fast enough to reduce, minimize or prevent non-ligand-labeled particles from binding or settling and slow enough to enable binding of ligand labeled particles.

In one embodiment, the particle flow is between 400-700 μm/s.

In one embodiment, the particle processing system includes a pair of electrodes operatively coupled across the functionalized portion for selectively changing the electrical potential across the polymer.

In one embodiment, the modulation of affinity with respect to ligand-receptor interactions at the functionalized portion is used to bind a ligand-labeled particle. In another embodiment, the modulation of affinity with respect to ligand-receptor interactions at the functionalized portion is used to release a previously bound ligand-labeled particle.

In one embodiment, the particle processing system is adapted for sorting particles in the particle processing system, wherein the modulation of affinity with respect to ligand-receptor interactions at the functionalized portion is used to facilitate the sorting.

In one embodiment, the particle processing system is adapted for analyzing or assaying particles in the particle processing system, wherein the modulation of affinity with respect to ligand-receptor interactions at the functionalized portion is used to facilitate the analyzing or assaying.

In another aspect, a method is disclosed for processing particles in a particle processing system at least a portion of which is functionalized with a receptor doped electroactive polymer, the method including applying a first electric potential across the polymer to facilitate binding of ligand-labeled particles.

In one embodiment, the invention provides methods for processing particles in a particle processing system at least a portion of which is functionalized with a receptor doped electroactive polymer. The methods include applying a first electric potential across the polymer to facilitate binding of ligand-labeled particles.

In one embodiment, the methods further include applying a second electric potential across the polymer to facilitate releasing previously bound ligand-labeled particles.

In one embodiment, the particle processing system is a microfluidic system.

In one embodiment, the functionalized portion is a tip of a biochemical actuator head included in the particle processing system.

In one embodiment, the particle processing system further includes an actuator operatively coupled relative to the biochemical actuator head, the method further comprising selectively positioning the biochemical actuator head within the particle processing system.

In one embodiment, the functionalized portion is at least a portion of a channel included in the particle processing system and wherein the applying the first electric potential across the polymer facilitates binding of ligand-labeled particles flowing through the channel.

In one embodiment, the methods further include providing a particle flow through the channel, wherein the particle flow is fast enough to reduce, minimize or prevent non ligand-labeled particles from binding or settling and slow enough to enable binding of ligand labeled particles.

In one embodiment, the particle flow is between 400-700 μm/s.

In one embodiment,n the first electric potential is applied across a pair of electrodes operatively coupled across the functionalized portion.

In one embodiment, the binding of the ligand-labled particles is for sorting particles in the particle processing system. In another embodiment, the binding of the ligand-labled particles is for analyzing or assaying particles in the particle processing system.

Other features and advantages of the present disclosure will become more apparent from the following detailed description and claims. Embodiments of the invention can include any combination of features described herein. In no case does the term “embodiment” necessarily exclude one or more other features disclosed herein, e.g., in another embodiment. The contents of all references, patent applications and patents, cited throughout this application are hereby expressly incorporated by reference.

### BRIEF DESCRIPTION OF THE DRAWINGS

FIG. 1 depicts an exemplary microfabricated conductive head functionalized with receptor-doped conductive polymers which may be used to dynamically modulate ligand-receptor interactions by controlling the oxidization and reduction states of the polymer, according to the present disclosure.

FIG. 2 depicts an exemplary fabrication method for a biochemical actuator head, according to the present disclosure.

FIG. 3 depicts using an exemplary biochemical actuator head to selectively grip, position and release protein coated beads, according to the present disclosure.

FIG. 4 depicts exemplary segmentation of adjacent protein-coated fluorescent beads, according to the present disclosure.

FIG. 5 depicts nanoassembly using a biochemical actuator head, according to the present disclosure.

FIG. 6 depicts multiplexing of nanoassembly using an array of biochemical actuator heads, according to the present disclosure.

FIG. 7 depicts the geometry of a disk electrode at the surface of a biochemical actuator head, according to the present disclosure.

FIG. 8 depicts selectively activate ligands on a cellular membrane using a biochemical actuator head, according to the present disclosure.

FIG. 9 depicts image-guided surgical procedures on live cells using a biochemical actuator head, according to the present disclosure.

FIG. 10 depicts an exemplary biochemical actuator head for interacting with a ferromagnet bead and reversibly flipping the domain thereof, according to the present disclosure.

FIG. 11 depicts an exemplary microfluidic system for reversible adhesion-based cell processing, according to the present disclosure.

FIG. 12 depicts an exemplary microfluidic system used to test reversible adhesion-based cell processing in a microchanel, according to the present disclosure.

FIG. 13 depicts the number of FN-coated and non-coated beads present on the channel surface before oxidation, after oxidation and before reduction, and after reduction during testing of the exemplary microfluidic system of FIG. 12, according to the present disclosure.

FIGS. 14A-D depict the (A) number and (B) percentage of beads bound and (C) number and (D) percentage of beads released for each of FN-coated beads with respect to an uncoated (conventional) microchannel, FN-coated beads with respect to the αFN-doped PPy-coated microchannel and uncoated beads with respect to the αFN-doped PPy-coated microchannel during testing of the exemplary microfluidic system of

FIG. 12, according to the present disclosure.

FIGS. 15A-B depict (A) number and (B) percentage of FN-coated and uncoated beads bound and unbound at different flow velocities during testing of the exemplary microfluidic system of FIG. 12, according to the present disclosure.

FIG. 16 depicts results for a recovery test, conducted using the exemplary microfluidic system of FIG. 12, according to the present disclosure.

### DETAILED DESCRIPTION

The present disclosure focuses on the development of integrated electromechanical systems, e.g., microelectromechanical systems (MEMS) and nanoelectromechanical systems (NEMS), utilizing conductive polymer instrumentation to selectively and reversibly bind proteins and other biomolecules. Specifically, the present disclosure involves, inter alia, the development of a biochemical actuator head for electromechanical systems, wherein the biochemical actuator head is instrumented with a receptor doped conductive polymer (e.g., polypyrrole) to reversibly control ligand-receptor interactions.

As used herein, “ligand” is intended to include a protein, enzyme, analyte, biomolecule, DNA, mRNA, fatty acid, drug compound, synthetic peptide, or any other moiety, compound or structure complimentary to, or able to bind to, a receptor.

As used herein, “receptor” is intended to include a monoclonal or polyclonal antibody or fragment thereof, any nucleic acid molecule, e.g., ssDNA or mRNA sequence, enzyme inhibitor, affinity probe, drug target, protein, biomolecule binding domain, or any other moiety, compound or structure complementary to, or able to bind to, a ligand.

As used herein, “ligand-receptor interaction” may be any interaction between a ligand and a receptor as defined herein.

As used herein, “body” or “particle” refers to a discrete unit of matter. Bodies/particles may be naturally occurring or synthetic, or may combine natural and synthetic components within a single particle. Bodies/particles may refer to biological particles. For example, particles may include cells (for example, blood platelets, white blood cells, tumorous cells or embryonic cells, spermatozoa, to name a few), liposomes, proteoliposomes, yeast, bacteria, viruses, pollens algae, or the like. Bodies/particles may also refer to non-biological particles. For example, bodies/particles may include metals, minerals, polymeric substances, glasses, ceramics, composites, or the like. In some embodiments, bodies/particles may include (macro) molecular species such as proteins, enzymes, polynucleotides, or the like. In exemplary embodiments, bodies/particles may include cells or beads with fluorochrome conjugated antibodies.

As used herein, “particle processing system” refers to a system for processing bodies/particles, wherein processing may include any action taken with respect to bodies/particles including but not limited to analysis, manipulation, sorting, assaying, incubation, staining, washing, and/or mixing thereof.

As used herein, “microfluidic system” refers to a system for processing, for conveying bodies/particles in a carrier fluid (liquid and/or gas), for example, for processing thereof. A particle processing system may, in exemplary embodiments, be a microfluidic system.

It is noted that the terms “ligand,” “receptor,” “ligand-receptor interaction,” “body,” “particle,” “particle processing system,” and “microfluidic system,” as used herein, may differ from the ordinary and customary meaning accorded such in the art. For example, as used herein both the ligand and the receptor in a ligand-receptor interaction may be any moiety, compound or structure, provided that the ligand and receptor compliment and are able to bind to one another in a specific manner. The “ligand” and the “receptor” can be a “body” or “particle”.

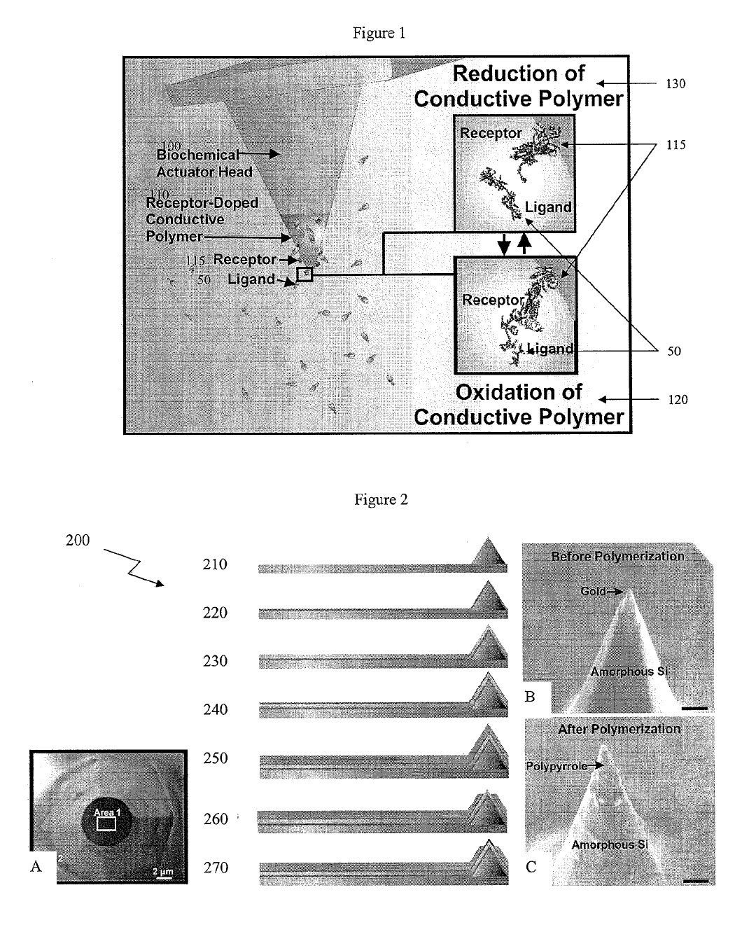

Referring now to FIG. 1, an exemplary biochemical actuator head 100 is depicted. The head 100 advantageously includes a tip 110 instrumented with an electroactive polymers, such as polypyrrole (PPy), doped with a receptor, e.g., antibodiy 115 (the head 100 is typically roughly conical). The electroactive polymer may further include dopant ions, polyions or surfactant molecules, e.g., to facilitate cation or anion exchange (depending on the ligand). Thus, for negatively charged ligand-receptor interactions, anionic dopants (e.g., Cl⁻, NO₃⁻, ClO₄⁻, SO₄²⁻, or dodecylbenzene sulfonate) may be advantageously incorporated into the conductive polymer matrix. Conversely, for positively charged ligand-receptor interactions, cationic dopants (e.g., Na⁺, N⁺, cetyltrimethylammonium chloride, dodecyltrimethylammonium chloride, or octyltrimethylammonium chloride) may be included in the conductive polymer matrix.

As contemplated herein, the biochemical actuator head 100 may be used to selectively and reversible modulate affinity with respect to ligand-receptor interactions at the tip 110 in response to changes in electric potential across the polymer.

Specifically, in exemplary embodiments, application of a positive potential to a polymer-electrolyte (e.g., NaCl solution) interface oxidizes 120 the polymer and facilitates binding of negatively charged antigens 50 to the antibodies 115 in the polymer matrix. Conversely, application of a negative potential reduces 130 the polymer and inhibits antibody-antigen interactions at the interface. Thus, by exploiting the propensity of the polymer, e.g., an antibody-doped PPy, to approach a charge neutral state during oxidation 120 and reduction 130, one is able to selectively and reversibly mediate antibody- antigen interactions as a function of applied electrical potential, frequency, and antigen concentration (notably, reversibility is not affected by the suppression of strong hydrophobic binding forces).

To illustrate, reduction (a) and oxidation (b) reactions for PPy doped with negatively charged antibodies (Ab⁻) and sulfate polyions (SO₄²⁻) in a salt buffer are provided below:

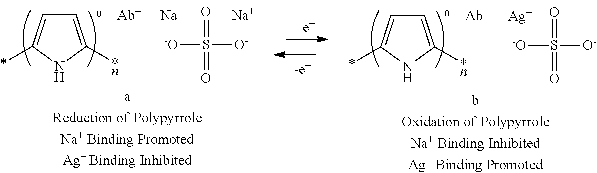

During reduction of PPy negative charges in the polymer are neutralized via interactions with Na⁺ ions. Conversely, during oxidation of PPy binding of negatively charged antigens (Ag⁻) is. facilitated such that polymer remains in a charge neutral state. Thus, the protein-doped, e.g., antibody-doped PPy is able to selectively and reversibly modulate antibody-antigen interactions by maintaining a charge neutral state in the PPy film. PPy substrates and other electroactive polymer films designed to mediate antibody-antigen interactions utilize the ability of PPy to interact with counter ions and biomolecules to minimize free charges in the polymer matrix. In a saline solution, application of a negative potential to a PPy film causes Na⁻ ions to neutralize negative charges present in the polymer. Consequently, interactions between negatively charged antibodies and negatively charged antigens are inhibited during reduction since they impede the ability of the polymer to maintain a charge neutral state. Conversely, during application of a positive potential to the PPy films (oxidation), the PPy films promote the addition of negative charges to approach a charge neutral state. As a result of the addition of negative charges, negatively charged antibody-antigen interactions occur at the PPy surface during oxidation. Antibodies entrapped in the PPy matrix act as anions, but because of their large size, they cannot move to balance PPy surface charges. Furthermore Cl⁻ diffusion into the polymer is not a significant effect in NaCl solutions, and CI⁻ will not displace the antibodies in the PPy.

In exemplary embodiments, the antigens 50 and antibodies 115 utilized may include fibronectin and its antibody (FN-αFN). See e.g., O'Grady M L, *Parker K K*, Dynamic control of protein-protein interactions, Langmuir, 2008 Jan. 1; 24(1):316-22, Epub 2007 Dec. 4, which, by reference, is hereby incorporated herein in its entirety. Fibronectin advantageously contains a particular domain structure, fibronectin type III, that is 4 nm in length when folded, but can extend to 29 nm, thus providing a 7-fold increase in length. Furthermore, the force required to denature and stretch the fibronectin (3.5-5 pN), is considerably less than the force required to break a protein-protein interface (10-30 pN). Thus, fibronectin may advantageously be exploited as a particularly mechanically robust protein label. Impedance spectroscopy results demonstrated that oxidation of αFN-doped PPy promotes selective FN binding to αFN antibodies and reduction of the polymer films facilitates FN release. This was demonstrated to be repeatable, over 20 redox cycles in samples on the millimeter length scale. Moreover, staircase potential electrochemical impedance spectroscopy (SPEIS) measurements indicated that the apparent reversibility of protein-doped, e.g., antibody-doped polypyrrole is due to the minimization of charge in the polymer films during oxidation and reduction. These charge transport characteristics can be utilized to selectively and reversibly control FN-αFN interactions, as well as to dynamically detect FN concentrations in solution. It is noted however, that the specific polymer chemistry utilized depends the ligand-receptor interaction of interest for a particular application. Thus, the present disclosure is not limited to the particular polymers and antigen/antibody pairs taught herein.

As noted above, ligand-receptor interactions may be reversibly modulated in electroactive polymer films such as PPy films. In particular, ligand-receptor interactions may be controlled using a control algorithm, e.g., a computer/processor implemented control algorithm. The control algorithm may advantageous apply characterizations of ligand-receptor interactions as functions of, e.g., applied potential, binding and release kinetics, and concentration. It is noted that characterizations of ligand-receptor interactions may also be used to determine optimal concentrations.

Exemplary characterizations of receptor-ligand interactions for implementation in a control algorithm, are provided below:

Assumptions:

The exemplary algorithm relies on the following assumptions: (1) receptor-ligand binding occurs over long timescales (>50 ms), i.e., such that charge transfer processes at the electrode tip are at equilibrium (only slow diffusion, migration and chemical reactions at the tip); (2) during binding, the binding constant k₁ is greater than the dissociation constant k₂; (3) the antibodies B are uniformly distributed at tip surface; and (4) a Guoy-Chapman double layer at the electrode tip. Thus:

$$\begin{matrix}\frac{\partial Φ}{\partial z} = {( \frac{8 {k}_{B} {Tn}^{0}}{{εε}_{0}} )}^{1 \text{/} 2} sin h ( \frac{zeΦ}{{k}_{B} T} ) \\ and & ( 1.1 ) \\ \frac{{\partial }^{2} Φ}{\partial {z}^{2}} = \frac{e}{{εε}_{0}} {Σn}_{i}^{0} {z}_{i} exp ( \frac{- {z}_{i} e Φ}{{k}_{B} T} ) & ( 1.2 )\end{matrix}$$

where Φ is electrostatic potential (V), k_{B} is Boltmann's constant (J/K), T is the absolute temperature (K), n⁰ is the number concentration of each ion in a z:z electrolyte (cm⁻³), z is the charge magnitude of each ion in a z:z electrolyte, e is the charge of an electron (C), ∈ is the dielectric constant (80 for water) and ∈₀ the permittivity of free space (C²N⁻¹m⁻²).

Constitutive Equations:

The flux Jᵢ of ligands at the tip is given by the Nernst-Planck equation, where both diffusion and migration of the ligands occurs over slow timescales in solution.

Thus:

$${J}_{A} ( r , z , t ) = - {D}_{A} ∇ {C}_{A} ( r , z , t ) - \frac{{z}_{i} F}{RT} {D}_{A} {C}_{A} ( r , z , t ) ∇ Φ \qquad ( 2.1 )$$

where C_{A}(r,z,t) is the concentration of ligand A in solution (M) as a function of radial distance (r) axial distance (z) and time (t) (see FIG. 7), D_{A} is the diffusion constant of ligand A in solution cm²/s, F is the Faraday constant (C) and R is the gas constant (J mol⁻'K⁻¹).

Therefore:

$$\frac{\partial {C}_{A} ( r , z , t )}{\partial t} = - ∇ \cdot {J}_{A} ( r , z , t ) + {R}_{r} \qquad ( 2.2 )$$

where Rᵥ is the bulk reaction rate:

Moreover, when ligand A and receptor B bind, they form a complex, denoted by AB. Binding of A to B occurs at rate k₁ (cm/s) and dissociation occurs at rate k₂ (cm/s).

A+B→^{k}^{₁}AB (2.3)

A+B←^{k}^{₂}AB (2.4)

Assuming that the concentration of receptor B remains constant and immobile over time and that (C_{B}(r,z)) is constant, the rate of formation of complex AB (C_{AB(r,z=}0,t)(M) is given by:

$$\frac{\partial {C}_{AB} ( r , t )}{\partial t} = {k}_{1} {C}_{A} ( r , z , t ) {C}_{B} ( r , z ) - {k}_{2} {C}_{AB} ( r , t ) \qquad ( 2.5 )$$

Binding and Release Functions

During binding, one assumes that k¹ [symbol] k². Thus, combining equations 2.2 and 2.3:

$$\frac{\partial {C}_{A} ( r , z , t )}{\partial t} = {D}_{A} {∇}^{2} {C}_{A} ( r , z , t ) + \frac{{Z}_{i} F}{RT} {D}_{A} ∇ {C}_{A} ( r , z , t ) {∇}^{2} Φ - {k}_{1} {C}_{A} ( r , z , t ) {C}_{B} ( r , z ) \qquad ( 3.1 )$$

Substituting equation 2.1:

$$\frac{\partial {C}_{A} ( r , z , t )}{\partial t} = {D}_{A} {∇}^{2} {C}_{A} ( r , z , t ) + \frac{{Z}_{i} F}{RT} {D}_{A} ∇ {C}_{A} ( r , z , t ) \frac{e}{{εε}_{0}} Σ {n}_{i}^{0} {z}_{i} exp ( \frac{- {z}_{i} e Φ}{{k}_{B} T} ) - {k}_{1} {C}_{A} ( r , z , t ) {C}_{B} ( r , z ) \qquad ( 3.2 )$$

Conversely, during release, one assumes k₂ [symbol] k₁. Thus combining equations 2.2 and 2.4 and substituting equation 2.1:

$$\frac{\partial {C}_{A} ( r , z , t )}{\partial t} = {D}_{A} {∇}^{2} {C}_{A} ( r , z , t ) + \frac{{Z}_{i} F}{RT} {D}_{A} ∇ {C}_{A} ( r , z , t ) \frac{e}{{εε}_{0}} Σ {n}_{i}^{0} {z}_{i} exp ( \frac{- {z}_{i} e Φ}{{k}_{B} T} ) + {k}_{2} {C}_{AB} ( r , t ) \qquad ( 4.1 )$$

In exemplary embodiments, e.g., wherein not all antibodies B are immobilized at the tip, receptor-ligand interactions away from the tip, e.g., in solution (M), are also considered. When considering such interactions the effect of migration may be ignored in favor of a diffusion-reaction model. Therefore:

$$\frac{\partial {C}_{A} ( r , z , t )}{\partial t} = {D}_{A} {∇}^{2} {C}_{A} ( r , z , t ) - {k}_{1} {C}_{A} ( r , z , t ) {C}_{B} ( r , z ) + {k}_{2} {C}_{AB} ( r , t ) \qquad ( 5.1 )$$

It is noted that, in applying equations 4.2, 5.1 and 6.1, It may be assumed that the limits of C_{A}(r,z,t) and (C_{B}(r,z) when r and z→∝ is equal to the starting bulk concentrations, C_{A}* and C_{B}*, at time 0:

C_{A}(r,z,0)=C_{A}* (6.1)

C_{B}(r.z)=C_{B}* (6.2)

Referring now to FIG. 2, an exemplary fabrication method 200 for a biochemical actuator head, e.g., the biochemical actuator head 100 of FIG. 1, is depicted. Typically, the biochemical actuator head is fabricated from a silicon head such as commonly used for electron force microscopy (EFM) (see step 210). In exemplary embodiments, the silicon head may be flattened (see image A in FIG. 2) during step 210, e.g., using a focused ion beam with an emission current of 50-100 pA at 30 kV. In step 220 a first metal adhesion layer, .e.g., a chromium (Cr) or titanium (Ti) adhesion layer, is deposited on a silicon (Si) head. Next, in step 230, an electrode layer, e.g., gold (Ag), is deposited on top of the first metal adhesion layer. In steps 240 and 250, respectively a second metal adhesion is deposited on top of the electrode layer and an amorphous-silicon (α—Si) layer is deposited on top of the second adhesion layer. A physical vapor deposition instrument such as e-beam evaporator may be used to deposit each of the layers in steps 220-240 (for an e-beam evaporator growth rates for the physical vapor deposition processes are between 1.0-2.5 Å/s in atmospheres of less than 2×10⁻⁷ Torr). In exemplary embodiments, the first and second adhesion layers may be approximately 10-20 nm thick, and the electrode layer may be approximately 300-400 nm thick. A plasma enhanced chemical vapor deposition instrument may be used to deposit the amorphous-silicon layer (step 250) e.g., in an atmosphere of 10 sccm Ar, 100.1 sccm SiH₄, and 0.3 sccm He at a pressure of 30 mTorr and a temperature of 20° C.). In exemplary embodiments the amorphous-silicon layer may be approximately 200 nm thick. In step 260, subsequent to the amorphous silicon layer having been deposited, the underlying electrode layer at the tip of the head is exposed (see image B in FIG. 2). For example, the electrode layer may be exposed by selectively etching the amorphous silicon layer at the tip, e.g., using a focused ion beam with an emission current of 10 pA at 30 kV. In exemplary embodiments, etching of tips may be achieved using a dual-beam instrument featuring both etching and scanning electron microscope (SEM) capabilities. Since prolonged exposure of the head to a high intensity focused ion beam will inevitably degrade the quality thereof, the SEM functionality may be used for focusing purposes prior to etching (in particular the instrument may be adjusted such that the eucentric point for the dual beams is positioned proximate to the tip). In Step 270, a receptor doped electroactive polymer layer is electropolymerized on the exposed electrode surface (see image C in FIG. 2). Electropolymerization facilitates incorporation of negatively charged ions, surfactants, dopants and/or biomolecules into the polymer. Thus, since, e.g., all antibodies, contain a negatively charged constant region at physiological pH (Hamilton, R.G “The Human IgG Subclasses” Calbiochem Corporation, 1990), any antibody may be incorporated into the polymer surface thereby providing robust flexibility in mediating antibody-antigen interactions of interest. In exemplary embodiments, a holder, e.g., a metallic cantilever holder may be utilized to hold the head or associated cantilever throughout electropolymerization. Thus, exposed metal regions of the holder may be insulated with vacuum grease.

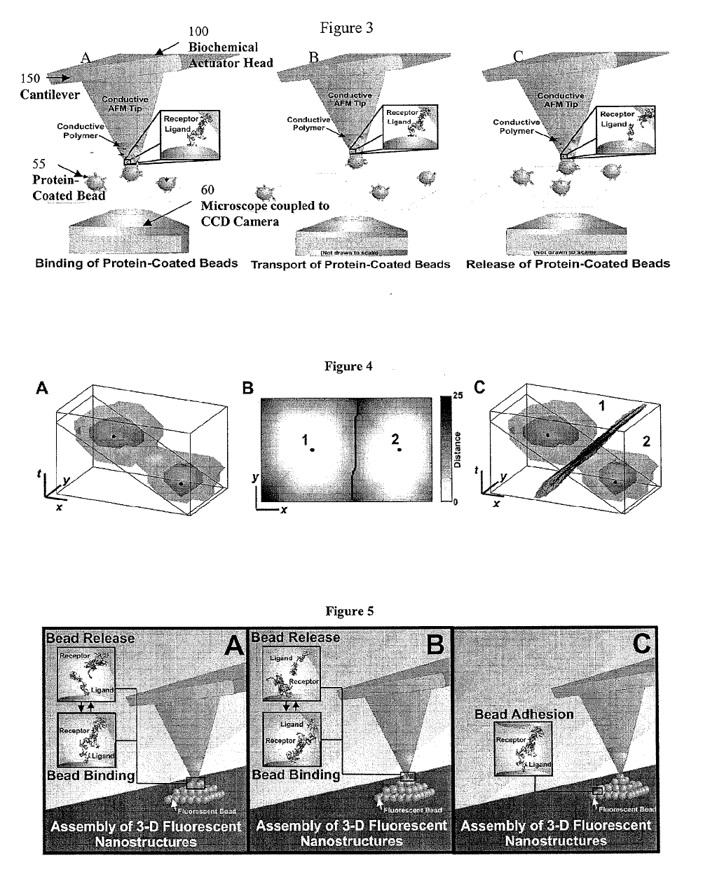

Referring now to FIG. 3, In exemplary embodiments, the biochemical actuator head 100, may be used to selectively grip (A), position (B) and/or release (C) ligand-labeled bodies/particles (e.g., protein coated beads 55). Thus, in some embodiments, the head 100 may advantageously be operatively coupled relative to one or more actuators, for example, piezoelectric actuators, thereby enabling the selective positioning of the head 100, e.g., relative to a target. In further exemplary embodiments, the head 100 may be advantageously associated with or integral with a cantilever (150), e.g., such as commonly used in electron force microscopy (EFM). The cantilever may advantageously facilitate coupling the head 100 relative to the one or more actuators. In exemplary embodiments, the cantilever may be characterized by a spring constant of 40-45 N/m.

As depicted in FIG. 3, real-time quality control and quantitative analysis of binding/release interactions (e.g., speed) and placement accuracy may be achieved, e.g., via fluorescent video microscopy using an inverted optical microscope coupled to a CCD camera 60. Custom image processing algorithms for position control of the head 100 are provided in Bray, et al., 2007 (Biophys J. 92(12):4433-43), which is incorporated herein its entirety. In general, the image processing algorithms may be advantageously used to extract locations of target ligand-labeled bodies/particles and guide the biochemical actuator head 100 with respect thereto. To illustrate, the following image processing procedures may be utilized to extract locations of, e.g., 100 nm protein-coated fluorescent beads from a confocal fluorescence image. A top-hat filter may be applied to remove variations in the background intensity across an image. This also allows bright objects, e.g., protein-coated fluorescent beads, which are smaller than a given size to be enhanced, while the remaining objects in the image are diminished. A thresholding approach may be used to automatically determine an upper boundary (T_{UB}) grayscale value defining a bead in the image. The image may then be binarized with increasing threshold values to generate a curve composed of the average area of the thresholded regions as a function of threshold value. The lower boundary (T_{LB}) grayscale value is defined as that value where the average object area is maximum. Thus, an optimal threshold is finally selected as the maximum value in the range of [T_{LB}, T_{UB].}

According to the present disclosure, a generalized second derivative test may be used to detect relative intensity maxima within the image (see Otsu, et al., 1979, IEEE Trans. Sys., Man., Cyber. 9: 62-66, which is incorporated herein its entirety). Each thresholded region R is analyzed for the presence of potential beads, which may be determined as a maximum embedded in the scalar n-dimensional data set. Specifically, the fluorescence values are defined in R as a multivariate function ƒ(ξ₁, ξ₂, ξ₃). The maxima are then calculated as the intersection of the zero level sets of the spatial partial derivatives of ƒ, i.e., ∂ƒ/∂ξ₁=0 ∩∂ƒ/∂ξ₂=0 ∩∂ƒ/∂ξ₃=0. The function ƒ is fit with an interpolating spline to precisely calculate the partial derivatives and the level sets are 3-D isosurfaces for fullframe fluorescent data. Next, relative maxima of R are calculated to avoid discretization effects (such as grid coarseness surrounding a peak) which may produce false negatives; and to produce a defined border delimiting the boundaries of the bead region for further processing. The relative maxima may be obtained analytically using the general second derivative test, as follows:

1. For each R, define the Hessian matrix H as the Jacobian of [∂ƒ/∂ν₁, ∂ƒ/∂ν₂, ∂ƒ/∂ξ₃], that is,

$$H = [ \begin{matrix}{\partial }^{2} f \text{/} \partial {ζ}_{1}^{2} & {\partial }^{2} f \text{/} \partial {ζ}_{1} \partial {ζ}_{2} & {\partial }^{2} f \text{/} \partial {ζ}_{1} \partial {ζ}_{3} \\ {\partial }^{2} f \text{/} \partial {ζ}_{2} \partial {ζ}_{1} & {\partial }^{2} f \text{/} \partial {ζ}_{2}^{2} & {\partial }^{2} f \text{/} \partial {ζ}_{2} \partial {ζ}_{3} \\ {\partial }^{2} f \text{/} \partial {ζ}_{3} \partial {ζ}_{1} & {\partial }^{2} f \text{/} \partial {ζ}_{3} \partial {ζ}_{2} & {\partial }^{2} f \text{/} \partial {ζ}_{3}^{2}\end{matrix} ] .$$

2. Define the k-th leading principal minor Mₖ as the determinant of the k×k submatrix of the n×n matrix H (where n=3) obtained by deleting the last (n−k) rows and columns from H.
3. The function f has a relative maxima at the location [ξ₁₍₀₎, ξ₂₍₀₎, ξ₃₍₀₎] if H evaluated at that location is negative definite, i.e., (−1)^{k}·Mₖ>0 for each k=1, . . . , n.

Thus, a set of sub-regions are produced which represent relative maxima in R, the neighborhoods of which contain actual maxima (i.e., fluorescent beads). Note that if a relative maximum region does not have a corresponding actual maximum, the region is typically labeled for removal. Furthermore, in some cases, beads are sufficiently close together (in either space or time) that multiple actual maxima lay within a single (x,y,t) relative maximum region, or multiple relative maxima lie within a single suprathreshold region (e.g., see FIG. 4A). The joined regions may be split using marker-controlled watershed segmentation using the maxima as starting markers (e.g., see FIG. 4B). The resulting watershed lines may then be used to divide the region (e.g., see FIG. 4C). As depicted in FIG. 4A, two neighboring beads are highlighted as three regions in (x,y,t) space: suprathreshold regions (green), relative maxima (blue) and actual maxima (black dots). A plane intersecting the actual maxima and bisecting the relative maxima and suprathreshold regions is shown in black outline. FIG. 4B depicts a Euclidean distance transformation on the intersecting plane shown in FIG. 4A with respect to the relative maxima. Actual maxima are shown as black dots. The watershed line is shown in red, dividing the space into two regions, labeled 1 and 2. FIG. 4C depicts (C) the original plot of FIG. 4A with the watershed surface superimposed in red, dividing the (x,y,t) space into the two labeled regions.

After determining the actual maxima, a filtering step may be used to identify and remove low intensity actual maxima which are likely spurious noise or out-of-focus beads from above the threshold. Thus, for each relative maximum region in ƒ(ξ₁, ξ₂, ξ₃), a function of the form α₁ξ₁+α₂ξ₂+α₃ξ₃=0 (representing a plane in three-dimensions) is fit to each region using a multivariate linear least-squares regression. If the correlation coefficient r² exceeds 95%, the region is close to being linear (i.e., “flat”) and is probably not a substantive bead.

In exemplary embodiments, a potentiostat may be utilized to electrochemically control and manipulate surface reactions at the head 100. Specifically, the potentiostat may be used to control a three-electrode electrochemical cell created utilizing a reference electrode (e.g., 0.8 mm diameter Ag/AgCl) and a counter electrode (e.g., 0.5 mm diameter 99.997% platinum wire). In general, the reference and counter electrodes are placed atop a work surface e.g., using a commercial fluid cell holder. In exemplary embodiments, the work surface may be a coverslip surface to allow for imaging, e.g., using a microscope and CCD camera. The potentiostat is electrically connected to the reference and counter electrode, as well as to the head 100. More particularly, the potentiostat may be electrically connected to a metallic cantilever holder which is electrically connected to the cantilever 150 which is associated or integral with the head 100. Typically, all exposed metal regions of the holder are insulated with vacuum grease (Dow Corning, Midland, Mich.).

The biochemical actuator head 100 disclosed herein, may be used in a wide array of applications including, without limitation, micro/nano assembly, examination of cellular signaling mechanisms, image-guided cell nanosurgery, particle processing and the like.

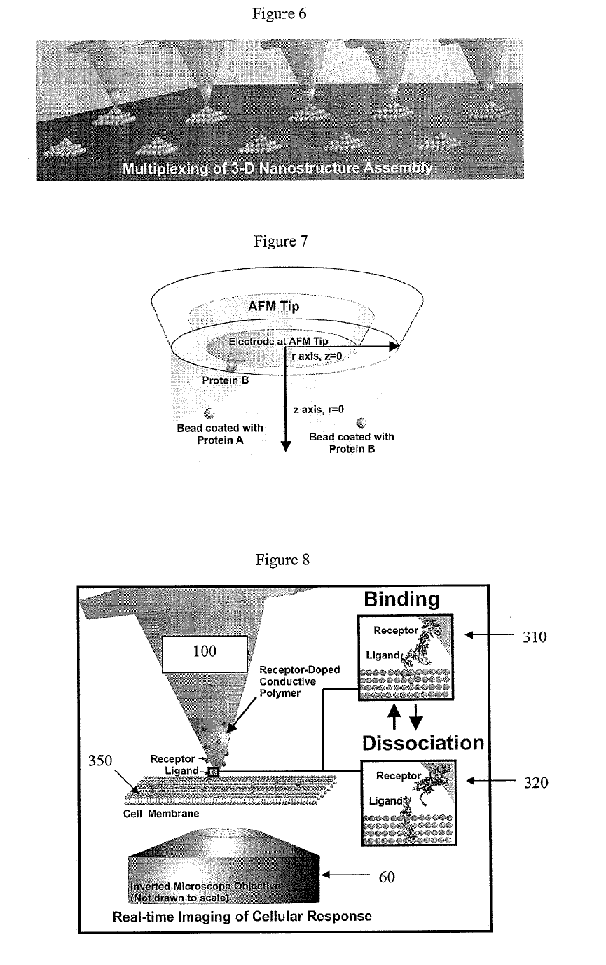

Referring now to FIG. 5, an exemplary nanoassembly process using a biochemical actuator head is depicted. The nanoassembly process may be advantageously used to assemble nanodevices, such as optical and electrical nanodevices, using e.g., nanowires, nanoparticles, flourecent beads, quantum dots and the like. As depicted, the biochemical actuator head is used to stack ligand-labeled bodies/particles, (specifically, protein coated beads) on a hydrophilic surface in a salt solution. The beads are stacked with alternating colors representing beads coated with an antibody, e.g., FN and beads coated with a corresponding antigen, e.g., anti-FN, respectively. Thus, alternating between antigen and antibody doped biochemical actuator heads (A and B) is required. The assembled structures may be advantageously reinforced by antibody-antigen binding as between layers (C). As depicted in FIG. 6, micro/nano assembly may also be advantageously multiplexed, e.g., using an array of cooperatively controlled biochemical actuator heads.

In exemplary embodiments, a biochemical actuator head may advantageously be used to mediate ligand-receptor interactions at the micro/nanoscale. Specifically, the spatiotemporal, mechanical and biochemical control provided by the biochemical actuator head and the systems and methods of the present disclosure may used to investigate cell signaling mechanisms, e.g., in healthy and diseased cardiac myocytes. Thus, e.g., a biochemical actuator head may be used to examine cell and tissue physiological responses under biochemical and/or mechanical stimulation. For example, cytoskeletal mechanics and calcium signaling may be examined by interacting with integrins in local areas of high and low cytoskeletal stresses. Thus, a biochemical actuator head may be used to investigate relationships between mechanosensitive ion channels, cytoskeletal architecture and calcium dynamics in engineered cardiac myocytes. A biochemical actuator head may also be used to investigate the effects of cell shape, cytoskeletal architecture and force frequency on nuclear mechanics. As depicted in FIG. 8, a biochemical actuator head 100 may be utilized to selectively activate ligands (or receptors) on a cellular membrane, e.g., via bonding 310 or disassociation 320 therewith. An imaging instrument, e.g., inverted microscope 60, may be advantageously be include for real-time monitoring of such activation.

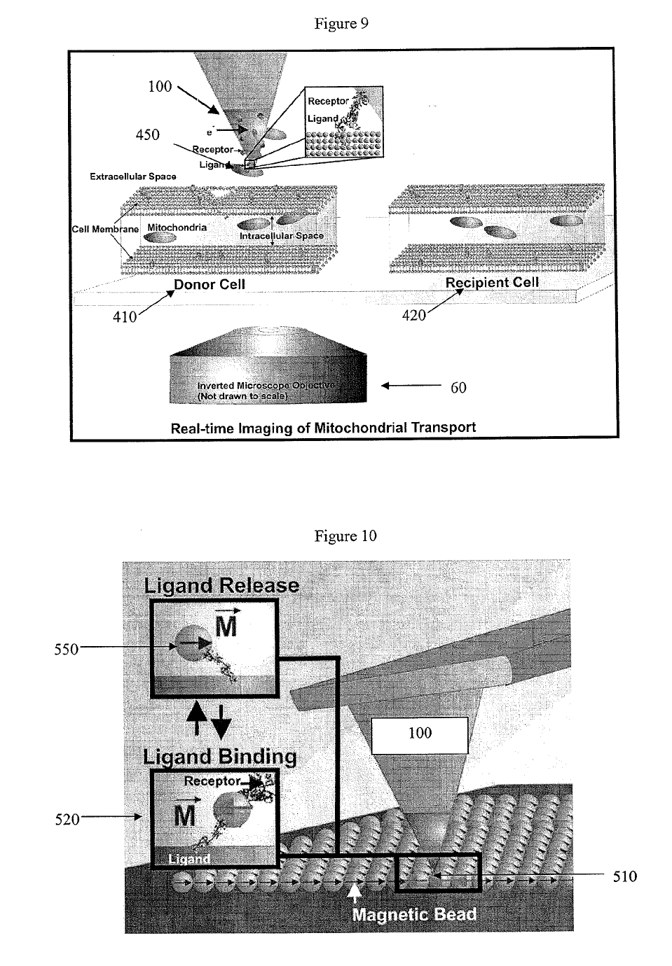

Moreover, as depicted in FIG. 9, a biochemical actuator head 100 may also be used to perform image-guided surgical procedures on live cells 410 and 420. Specifically, FIG. 9 depicts assembly of a ‘metabolic super cell,” e.g., wherein mitochondria 450 are extracted from a donor cell 410 using the biochemical actuator head 100 and inserted into a recipient cell 420. Again the procedure may be controlled and monitored using an imaging instrument, e.g., inverted microscope 60.

Referring now to FIG. 10, a magnetic biochemical actuator head 100 may be coupled to ferromagnet beads 550 coated with ligands of interest. When the receptor-doped tip interacts with a bead 510, the ferromagnetic domain of the bead is flipped 520, which can be measured via an output current connected to the ferromagnetic bead array. This offers a method of fast, reversible method of memory storage.

In other exemplary embodiments, a biochemical actuator head may advantageously be used to facilitate particle processing, for example, particle analysis, manipulation, sorting, assaying, incubation, staining, washing, mixing and other processes known in the art. Thus, in some embodiments, a biochemical actuator head may be operatively associated with a particle processing system, for example, a microfluidic system, for reversibly binding bodies/particles, for example, cells, in the system. In exemplary embodiments, the biochemical actuator head may be associated with an actuator for selectively positioning particles/bodies within the particle processing system. In other embodiments of the invention, a particle processing system is not operatively associated with a biochemical actuator head.

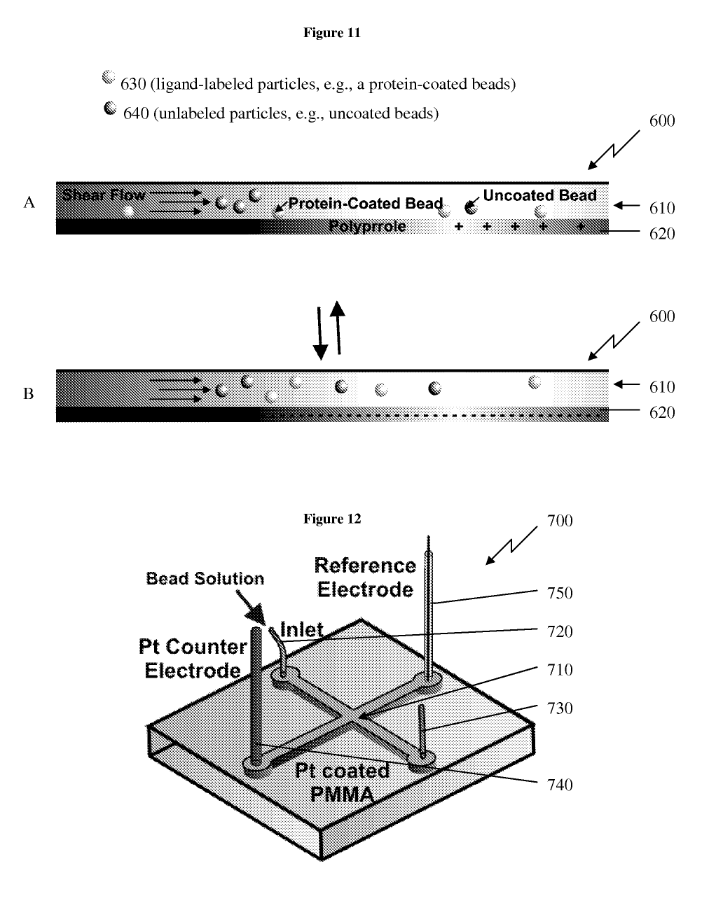

With reference to FIGS. 11A-B, an exemplary microfluidic system 600 for reversible adhesion-based cell processing is depicted. The microfluidic system 600 may include a microchannel 610 formed, coated or otherwise associated with a receptor doped conductive polymer 620 such as a receptor doped polypyrrole. In general, the receptor doped conductive polymer 620 may be used to selectively bind and release ligand-labeled particles 630, e.g., protein-coated beads, flowing through the microchannel 610 by changing applied voltage. In exemplary embodiments, as depicted in FIG. 11A, a positive voltage may be applied to/across the receptor doped conductive polymer 620 to bind ligand-labeled particles 630. In other embodiments, as depicted in FIG. 11B, a negative voltage may be applied to/across the receptor doped conductive polymer 620 to release ligand-labeled particles 630. It is noted that unlabeled particles 640 are ideally unaffected. In exemplary embodiments, a shear flow (e.g., drag forces of 42-98 pN and wall shear stresses of 12-21 mPa) may be applied minimize unwanted adhesion, e.g., due to settling, of unlabeled particles 640.

With reference to FIG. 12, an exemplary microfluidic system 700 used to test reversible adhesion-based cell processing in a microchanel 710 is depicted. Polypyrrole was polymerized on the surface of the microchannel. Inlet 720 and outlet 730 ports were setup opposite counter 740 and reference 750 electrodes.

In experiments conducted, Human fibronectin (FN) and anti-fibronectin antibody (αFN) were selected as the ligand and receptor of interest. FN, αFN and pyrrole monomer were stored at 4° C. until use. Analytical reagent grade Na₂SO₄, NaCl, KCl, CaCl₂, MgCl₂, NaH₂PO₄, HEPES [4-(2-hydroxyethyl)-1-piperazineethanesulfonic acid], and glucose were acquired and a normal Tyrode's (NT) solution was prepared with (in mmol/L) 135 NaCl, 5.4 KCl, 1.8 CaCl₂, 1 MgCl₂, 0.33 NaH₂PO₄, 5 HEPES, and 5 glucose. The pH of the NT solution was equilibrated to 7.40 at 37° C. with the addition of NaOH or HCl in order to remain consistent with previous cell and tissue electrophysiology studies. Fluorescent 15 μm diameter microspheres were used for flow experiments, where the concentration of beads in the NT solution was 250×10³ beads per ml, and 1×10⁴ beads per ml for experiments conducted with a “high” concentration of beads.

A versatile modular potentiostat was used for electropolymerization, impedance and potentiostatic measurements. In test embodiments, the counter electrode 740 was a 0.25 mm diameter 99.95% gold wire and the reference electrode 750 was an Ag/AgCl saturated KCl electrode and a 0.25 mm diameter 99.997% platinum wire (Alfa Aesar, Ward Hill, Mass.) counter electrode. All applied voltages are given versus the Ag/AgCl reference electrode. Fluorescence imaging was performed on a Zeiss M² Bio stereomicroscope using a Zeiss AxioCam MRM camera at a frame rate of 9 frames/s.

In test embodiments, the microchannel 710 was produced by etching a channel (length 10 mm, width 200 μm and height 100 pm) in poly(methyl methacrylate) (PMMA) using a VersaLaser engraving tool. A thick layer of platinum/palladium (Pt/Pd) was deposited on the microchannel surface using a sputter coater. A thin, double sided laminate sheet was used to attach a PMMA mold with 3 mm diameter inlets on top of the microchannel, in order to create the inlet 720 and outlet 730 ports as well as inlets for the counter 740 and Ag/AgCl reference 750 electrodes. Pyrrole was electropolymerized galvanostatically on the microchannel to form polypyrrole (PPy) from a solution of 0.1 M pyrrole dissolved in 0.01 M Na₂SO₄ and was calibrated to pH 7.40 before the addition of antibodies. In order to create αFN-doped PPy films, αFN was included in the electropolymerization solution at a concentration of 360 μg/ml. Current densities between 1.0 and 1.5 mA/cm² for a surface area of approximately 1.0 cm² were employed for up to 15 minutes versus Ag/AgCl to polymerize the PPy.

Oxygen was not removed from the solution during polymerization.

In experiments conducted, the number of beads bound and released from the αFN-doped PPy was quantified by first applying oxidation potentials of +600 mV (vs. Ag/AgCl) for 1 minute while collecting images using the stereomicroscope.

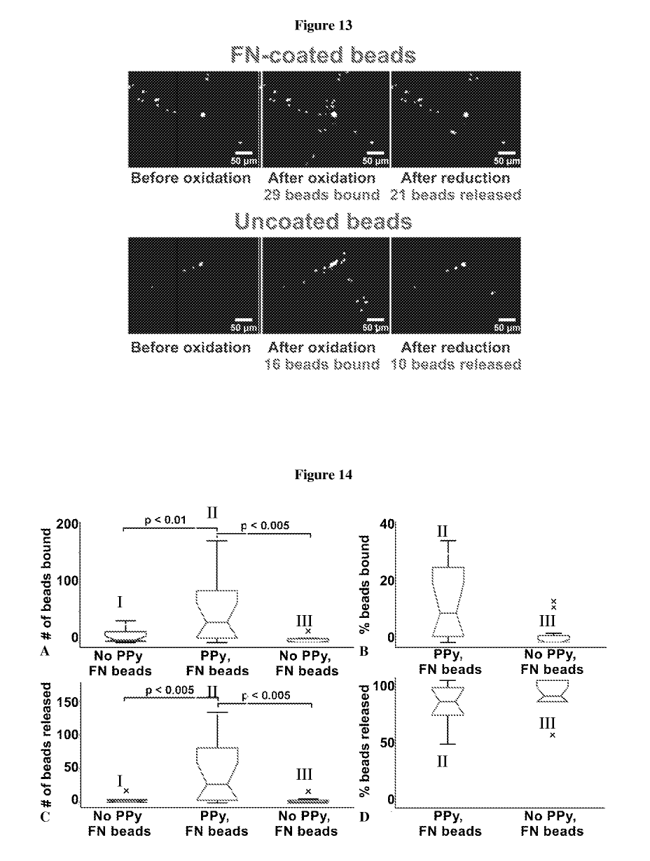

Reduction potentials of −500 mV (vs. Ag/AgCl) were subsequently applied for 1 minute while imaging particle flow. The number of beads (FN-coated and uncoated) present on the microchannel surface was quantified using an image processing algorithm in MATLAB as shown in FIG. 13. In particular, the number of beads bound was calculated as the number of beads present on the channel surface after oxidation subtracted from the number of beads on the microchannel surface before oxidation. Similarly, the number of beads released from the microchannel was calculated based on the number of beads present after reduction subtracted from the number of beads on the microchannel surface before reduction. To calculate the flow velocities in the microchannel, the displacement of each bead was calculated between each frame, and multiplied by the μm/pixel ratio of the image, as well as divided by the time between frames (generally 110 ms). Beads which entered the field of view but never exited as a result of binding to the channel surface were recorded as “binding” events. Kruskal Wallis non-parametric one-way analysis of variance was used to determined statistical significance between data points.

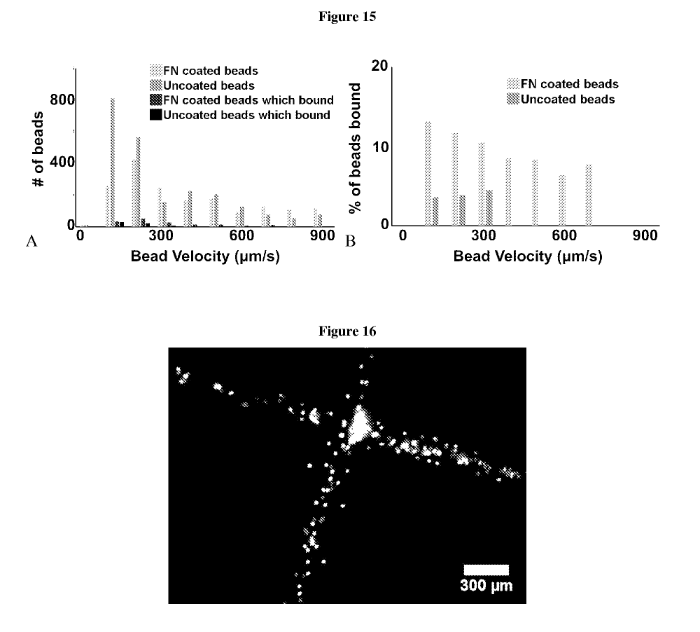

Tests were conducted in order to optically verify that FN beads were selectively binding to the PPy-coated microchannel surface. A low velocity flow of bead solution (e.g., bead velocities less than 300 μm/s) was applied for one minute during oxidation and reduction of the PPy-coated microchannel surface. FIGS. 14A-D depict results for the (A) number and (B) percentage of beads bound and (C) number and (D) percentage of beads released for each of (I) FN-coated beads with respect to an uncoated (conventional) microchannel, (II) FN-coated beads with respect to the αFN-doped PPy-coated microchannel and (II) uncoated beads with respect to the αFN-doped PPy-coated microchannel.

As shown in FIG. 14A, eight times more FN-coated beads bound to the PPy-coated microchannel surface (median=33.5, n=14 experiments) as compared to uncoated beads (median=4, n=14 experiments) and FN-coated beads in an uncoated microchannel (median=0, n=7 experiments). The number of uncoated beads bound to the microchannel surface and FN-coated beads bound to an uncoated microchannel were found to be statistically insignificant, indicating the “binding” of uncoated beads to the PPy-coated microchannel can largely be ascribed to settling and non-specific interactions of the beads with the PPy surface. Furthermore, as depicted in FIG. 14B, approximately 10% of the FN coated beads (as a percentage of total FN coated beads flowing through the microchannel during the one minute oxidation period) bound to the microchannel surface as compared to 1% of the uncoated beads (as a percentage of total uncoated beads flowing through the microchannel during the one minute oxidation period). This demonstrates, the ability of FN-coated beads to bind with molecular specificity.

In addition, the FN-coated beads consistently released from the PPy-microchannel surface during reduction with the same low flow of bead solution (bead velocities less than 300 μm/s) applied for one minute. The increase in the number of beads at the microchannel surface during oxidation depicted in FIG. 14A and the decrease in the number of beads at the microchannel surface during reduction depicted in FIG. 14C indicates the ability of antibody-doped PPy to bind and release charged particles by toggling the applied voltage. As shown in FIGS. 14C-D, in general 75-95% of the FN-coated beads were released from the microchannel surface and 80-100% of the uncoated beads. In general, these results demonstrate the ability of a PPy-coated microchannel to mediate the binding and release of protein-coated beads by changing the voltage applied to the PPy surface.

In tests conducted, the ability of FN-coated beads to bind to the microchannel surface was observed to be dependent on adhesion force at the bead surface relative to the drag force on the bead. Since drag force may be dependent on the flow velocity in the microchannel, the efficiency of bead binding was investigated as a function of flow rate and bead velocity. The results of this investigation are depicted in FIG. 15A-B, in terms of (A) number and (B) percentage of FN-coated and uncoated beads bound and unbound at different flow velocities.

As shown in FIGS. 15A-B, non-specific settling/binding of uncoated beads occurred for flow velocities of 100-300 μm/s, corresponding to drag forces of 14-42 pN and wall shear stresses of 3-9 mPa. However, FN-coated beads bound with a higher efficiency than uncoated beads and for a larger range of flow velocities, further demonstrating the specificity of antibody-doped polypyrrole. In addition, an average of 7-10% of FN beads bound to the PPy microchannel surface. In essence, these results indicate that bead velocities of 400-700 μm/s (drag forces of 42-98 pN and wall shear stresses of 12-21 mPa) permit FN adhesion to the PPy-coated microchannel surface while generating drag forces (>42 pN) too strong to allow for non-specific bead settling and protein adhesion.

In exemplary embodiments, reversible adhesion-based cell processing technology such as disclosed herein may be used to recover rare cell populations of interest. For example, as shown in FIG. 16, approximately 35% more protein-coated (white) beads bind to antibody-doped polypyrrole as compared to uncoated (grey) beads after 10 minutes. Furthermore, by using optimized shear flow, e.g., flow velocities of 400-700 μm/s, the proportion of bound protein-coated beads may be enhanced. The proportion of bound protein-coated beads may also be improved by increasing initial bead concentration (e.g., 2-3) or by iterating the recovery process, e.g., to increase initial FN-coated bead concentration each time.

The particle processing systems of the invention are useful for a wide array of applications including, without limitation, any microelectromechanical and nanoelectromechanical system application. For example, the apparatus, systems and methods of the present invention may be applied to biotechnology and/or medical diagnostic methods and applications such as, for example, label-free methods and technologies, which include analysis, manipulation, counting, sorting, assaying, incubation, staining, washing, and/or mixing of particles, e.g., biomolecules, such as cell, chromosomes, screening assays to identify a molecule of interest, to recover rare cell populations of interest, such as cancer cells, and/or stem cells, a lab-on a chip, to assess the extent of bacteria and cell adhesion as a function of flow velocity, to examine various types of protein-protein interactions as a function of shear force.

The following examples are set forth as being representative of the present invention. These examples are not to be construed as limiting the scope of the invention as these and other equivalent embodiments will be apparent in view of the present disclosure, figures, and accompanying claims.

### EXAMPLES

Introduction

Flow cytometry is a pervasive technique in biomedical research, since it permits highly sensitive counting and sorting of microscopic particles, such as cells and chromosomes. Yet, commercially available flow cytometers are expensive, mechanically complex, and require specialists to operate. For this reason microfluidic flow cytometers are favorable for benchtop sorting of cells and particles.

Most existing microfluidic flow cytometers allow for recovery of the cell population of interest, but they do not provide the incredible sensitivity of adhesion-based cell separation, nor do they have the capability to deal with the fluid complexity of large volumes of whole blood samples (Dittrich and Manz, Nature Reviews Drug Discovery, vol. 5, no. 3, pp. 210-218, 2006; El-Ali, et al. Nature, vol. 442, no. 7101, pp. 403-411, 2006; M. Toner and D. Irimia, Annual Review of Biomedical Engineering, vol. 7, pp. 77-103, 2005). Therefore, in order to exploit the enhanced sensitivity of adhesion-based cell separation and be able to recover rare cell populations of interest, technologies to detach cells in microfluidic devices after adhesion must be developed.

Yet, few studies have focused on the detachment of cells after capture in microfluidic devices. Towards this end, the goal of this study was to demonstrate that polypyrrole could be utilized to permit selective and reversible binding and release of protein-coated beads, which act as cell ‘mimics’ (FIG. 11). This strategy of electrochemical detachment does not involve sophisticated chemical synthesis, and it further allows for measurements of protein binding kinetics using impedance spectroscopy. The results presented herein demonstrate that polypyrrole-coated microchannels can be utilized to bind and release protein-coated beads of interest during flow by changing the voltage applied to the polypyrrole.

Moreover, the results presented herein indicate that flow velocities of <700 μm/s are necessary to promote bead adhesion. In general, 10% of protein coated beads bound to the polypyrrole-coated microchannel surface during low flow of bead solution as compared to <1% of uncoated beads. In addition, due to the precise control of flow velocity throughout the microfluidic channel, the technology can also be utilized to assess the extent of bacteria and cell adhesion as a function of flow velocity. Since polypyrrole-coated microchannels permit selective and reversible protein-protein interactions and allow for sensitive control of flow rate, this experimental setup can be applied to further examining various types of protein-protein interactions as a function of wall shear force.

### Materials and Methods

Solution Preparation

Human fibronectin (FN) (BD Biosciences, Franklin Lakes, NJ) and anti-fibronectin antibody (αFN) (Developmental Studies Hybridoma Bank, University of Iowa, Iowa) were used as the antigen and antibody of interest. Pyrrole monomer was purchased from Aldrich Chemical Company (St. Louis, Mo.). The FN, αFN and pyrrole were stored at 4° C. until use. Analytical reagent grade Na2SO4, NaCl, KCl, CaCl2, MgCl2, NaH2PO4, HEPES [4-(2-hydroxyethyl)-1-piperazineethanesulfonic acid], and glucose were acquired from Aldrich Chemical Company (St. Louis, Mo.). A normal Tyrode's (NT) solution was prepared with (in mmol/L) 135 NaCl, 5.4 KCl, 1.8 CaCl2, 1 MgCl2, 0.33 NaH2PO4, 5 HEPES, and 5 glucose. The pH of the NT solution was equilibrated to 7.40 at 37° C. with the addition of NaOH or HCl in order to remain consistent with previous cell and tissue electrophysiology studies. Fluorescent 15 μm diameter microspheres (Invitrogen, Carlsbad, Calif.) were used for flow experiments in NT, where the concentration of beads in NT was 250×103 beads per ml, and 1×104 beads per ml for experiments conducted with a high concentration of beads.

Apparatus

A Versatile Modular Potentiostat (Princeton Applied Research, Oak Ridge, Tenn.) was used for electropolymerization, impedance and potentiostatic measurements. The working electrode used for macroscale electrochemical experiments was a 0.25 mm diameter 99.95% gold wire (Alfa Aesar, Ward Hill, Mass.). The reference electrode was an Ag/AgCl saturated KCl electrode (Cypress Systems, Lawrence, Kans.) and a 0.25 mm diameter 99.997% platinum wire (Alfa Aesar, Ward Hill, Mass.) counter electrode. All applied voltages are given versus the Ag/AgCl reference electrode. Fluorescence imaging was performed on a Zeiss M2 Bio stereomicroscope (Carl Zeiss, Dresden, Germany) using a Zeiss AxioCam MRM camera at a frame rate of 9 frames/s.

Microchannel Fabrication

Microchannels of length 10 mm, width of 200 μm and height of 100 μm were etched in plexiglass (McMaster-Carr, Chicago, Ill.) using a VersaLaser engraving tool (Universal Laser Systems, Scottsdale, Ariz.). A thick layer of Pt/Pd was deposited on the microchannel surface using a sputter coater (Cressington Scientific Instruments, Watford, England). A thin, double sided laminate sheet (Fralock, Valencia, Calif.) was used to attach a plexiglass mold with 3 mm diameter inlets on top of the microchannels, in order to create inlet and outlet ports for the fluid, as well as inlets for the Ag/AgCl reference electrode and counter electrode (FIG. 12).

Pyrrole was electropolymerized galvanostatically on the microchannels to form polypyrrole (PPy) from a solution of 0.1 M pyrrole dissolved in 0.01 M Na2SO4 and was calibrated to pH 7.40 before the addition of antibodies. In order to create αFN-doped PPy films, αFN was included in the electropolymerization solution at a concentration of 360 μg/ml. Current densities between 1.0 and 1.5 mA/cm2 for a surface area of approximately 1.0 cm2 were employed for up to 15 minutes versus Ag/AgCl to polymerize the PPy. Oxygen was not removed from the solution during polymerization.

Flow Analysis

In order to quantify the number of beads bound and released from the αFN-doped PPy, oxidation potentials of +600 mV (vs. Ag/AgCl) were applied for 1 minute while collecting images with the Zeiss stereomicroscope. Reduction potentials of −500 mV (vs. Ag/AgCl) were subsequently applied for 1 minute while imaging particle flow. The number of beads present on the microchannel surface was quantified using an image processing algorithm in MATLAB (MathWorks, Natick, Mass.), as shown in FIG. 13. The number of beads bound was calculated as the number of beads present on the channel surface after oxidation subtracted from the number of beads on the microchannel surface before oxidation (FIG. 13B). Similarly, the number of beads released from the microchannel was calculated based on the number of beads present after reduction subtracted from the number of beads on the microchannel surface before reduction.

To calculate the flow velocities in the microchannel, the displacement of each bead was calculated between each frame, and multiplied by the μm/pixel ratio of the image, as well as divided by the time between frames (generally 110 ms). Beads which entered the field of view but never exited as a result of binding to the channel surface were recorded as ‘binding’ events. Kruskal Wallis non-parametric one-way analysis of variance (ANOVA) was used to determined statistical significance between data points.

Results and Discussion

Selective Binding of Protein-Coated Beads

In order to optically verify that FN beads were selectively binding to the PPy-coated microchannel surface, low flow of bead solution (bead velocities <300 μm/s) was applied for one minute during oxidation and reduction of the PPy-coated microchannel surface. A slight flow of bead solution was applied during these experiments to prevent settling and non-specific adhesion of uncoated beads to the microchannel surface, such that the effects of FN protein binding vs. settling of uncoated beads could be distinguished. As shown in FIG. 14A, eight times more FN-coated beads bound to the PPy-coated microchannel surface (median=33.5, n=14 experiments) as compared to uncoated beads (median=4, n=14 experiments) and FN-coated beads in an uncoated microchannel (median=0, n=7 experiments).

The number of uncoated beads bound to the microchannel surface and FN-coated beads bound to an uncoated microchannel were found to be statistically insignificant, indicating the ‘binding’ of uncoated beads to the PPy-coated microchannel can largely be ascribed to settling and non-specific interactions of the beads with the PPy surface. Furthermore, as a percentage of total beads flowing through the microchannel during the one minute oxidation period, approximately 10% of the FN coated beads bound to the microchannel surface as compared to 1% of the uncoated beads (FIG. 14B), demonstrating the ability of FN-coated beads to bind with molecular specificity.

In addition, the FN-coated beads consistently released from the PPy-microchannel surface during reduction with the same low flow of bead solution (bead velocities <300 μm/s) applied for one minute. The increase in the number of beads at the microchannel surface during oxidation (FIG. 14a) and decrease during reduction (FIG. 14c) while the same low flow of bead solution was applied indicates the ability of antibody-doped PPy to bind and release charged particles by toggling the applied voltage. As shown in FIGS. 14c and 14d, in general 75-95% the FN-coated beads released from the microchannel surface and 80-100% of the uncoated beads. In general, these results demonstrate the ability of PPy-coated microchannels to mediate the binding and release of protein-coated beads by changing the voltage applied to the PPy surface.

Dependence of Bead Binding on Flow Rate

The ability of FN-coated beads to bind to the microchannel surface depends on the adhesion force at the bead surface relative to the drag force on the bead. Since the drag force is dependent on the flow velocity in the microchannel, the efficiency of bead binding was investigated as a function of flow rate and bead velocity. As shown in FIG. 15, non-specific binding of uncoated beads occurred for flow velocities of 100 μm/s-300 μm/s, corresponding to drag forces of 14-42 pN and wall shear stresses of 3-9 mPa. However, FN-coated beads bound with a higher efficiency than uncoated beads and for a larger range of flow velocities, further demonstrating the specificity of antibody-doped polypyrrole. In addition, an average of 7-10% of FN beads bound to the PPy microchannel surface. In essence, these results indicate that bead velocities of 400 -700 μm/s (drag forces of 42-98 pN and wall shear stresses of 12-21 mPa) permit FN adhesion to the PPy-coated microchannel surface while generating drag forces (>42 pN) too strong to allow for non-specific bead settling and protein adhesion.

This technology could be used to exploit the enhanced sensitivity of adhesion-based cell and particle separation and to recover rare cell populations of interest. For instance, as shown in FIG. 16, approximately 35% more protein-coated (white) beads bind to antibody-doped polypyrrole as compared to uncoated (gray) beads after 10 minutes. By enhancing the bead concentration 2-3 fold and using flow velocities of 400-700 μm/s, the proportion of bound protein-coated beads can be enhanced, and these beads can be recovered after adhesion by simply changing the voltage applied to the microchannel. In addition, due to the precise control of flow velocity throughout the microfluidic channel, the technology could also be utilized to assess the extent of bacteria and cell adhesion as a function of flow velocity. Since polypyrrole-coated microchannels permit selective and reversible protein-protein interactions and allow for sensitive control of flow rate, this experimental setup could be applied to further examine various types of protein-protein interactions as a function of shear force.

### SUMMARY

These results described above demonstrate that polypyrrole-coated microchannel doped with antibodies for proteins can be utilized to permit selective and reversible binding and release of protein-coated beads, which act as cell ‘mimics.’ The microchannels can be utilized to bind and release protein-coated beads of interest during flow by changing the voltage applied to the polypyrrole. The results presented herein indicate that flow velocities of <700 μm/s and drag forces <98 pN (wall shear stresses <21 mPa) are able to promote bead adhesion. In general, 10% of protein coated beads bound to the polypyrrole-coated microchannel surface during low flow of bead solution as compared to <1% of uncoated beads. The technology can be utilized to exploit the enhanced sensitivity of adhesion-based cell separation assays in order to recover cell populations of interest.

Although the present disclosure has been described with reference to exemplary embodiments and implementations thereof, the disclosed apparatus, systems and methods are not limited to such exemplary embodiments/implementations. Rather, as will be readily apparent to persons skilled in the art from the description provided herein, the disclosed apparatus, systems and methods are susceptible to modifications, alterations and enhancements without departing from the spirit or scope of the present disclosure. Accordingly, the present disclosure expressly encompasses all such modifications, alterations and enhancements within the scope hereof. Other embodiments are within the following claims:

1. An elecromechanical system comprising:
a biochemical actuator head having a tip functionalized with a receptor doped electroactive polymer, whereby the biochemical actuator head is able to selectively and reversibly modulate affinity with respect to ligand-receptor interactions at the tip in response to changes in electric potential across the polymer, and
an actuator operatively coupled relative to the biochemical actuator head for selectively positioning the biochemical actuator head.

2. The electromechanical system of claim 1, wherein the electroactive polymer is polypyrole (PPy).

3. The electromechanical system of claim 3, wherein the receptor is an antibody and the ligand is an antigen.

4.-20. (canceled)

21. A method for selectively and reversibly controlling ligand-receptor interactions using an elecromechanical system including a biochemical actuator head having a tip functionalized with a receptor doped electroactive polymer, whereby the biochemical actuator head is able to selectively and reversibly modulate affinity with respect to ligand-receptor interactions at the tip in response to changes in electric potential across the polymer, the method comprising:
applying a first electric potential across the polymer to facilitate binding of a ligand at the tip; and
applying a second electric potential across the polymer to facilitate releasing the ligand from the biochemical actuator head.

22. The method of claim 21, wherein the electroactive polymer is polypyrole (PPy).

23. The method of claim 22, wherein the ligand is an antigen and wherein the receptor electroactive polymer is doped with an antibody for the antigen.

24.-27. (canceled)

28. The method of claim 21, wherein the ligand is associated with a ferromagnet bead and wherein the method is used to reversibly flip the domain thereof.

29.-39. (canceled)

40. A biochemical actuator head comprising a tip functionalized with a receptor doped electroactive polymer, wherein the biochemical actuator head is adapted to selectively and reversible modulate affinity with respect to ligand-receptor interactions at the tip in response to changes in electrical potential across the polymer.

41. The biochemical actuator head of claim 40, wherein the electroactive polymer is polypyrole (PPy).

42. The biochemical actuator of claim 40, wherein the receptor is an antibody and the ligand is an antigen.

43.-48. (canceled)

49. A method for manufacture of a biochemical actuator head, the method comprising
depositing a first metal adhesion layer on silicon (Si) head,
depositing an electrode layer on top of the first metal adhesion layer,
depositing a second adhesion layer on top of the electrode layer,
depositing an amorphous silicon (a-Si) on top of the second adhesion layer, exposing the underlying electrode layer at the tip of the head using a focused ion beam, and
electropolymerizing a receptor electroactive polymer on the exposed electrode surface.

50.-55. (canceled)

56. A particle processing system at least a portion of which is functionalized with a receptor doped electroactive polymer whereby the particle processing system is adapted to selectively and reversible modulate affinity with respect to ligand-receptor interactions at the functionalized portion in response to changes in electrical potential across the polymer.

57. The particle processing system of claim 56, wherein the particle processing system is a microfluidic system.

58. (canceled)

59. (canceled)

60. The particle processing system of claim 56, wherein the functionalized portion is at least a portion of a channel included in the particle processing system.

61. The particle processing system of claim 60, wherein the modulation of affinity with respect to ligand-receptor interactions at the functionalized portion is used to reversibly bind ligand-labeled particles flowing through the channel.

62. The particle processing system of claim 61, wherein the particle processing system is adapted to provide a particle flow, wherein the particle flow is fast enough to reduce, minimize or prevent non-ligand-labeled particles from binding or settling and slow enough to enable binding of ligand-labeled particles.

63. The particle processing system of claim 62, wherein the particle flow is between 400-700 μm/s.

64.-68. (canceled)

69. A method for processing particles in a particle processing system at least a portion of which is functionalized with a receptor doped electroactive polymer, the method comprising applying a first electric potential across the polymer to facilitate binding of ligand-labeled particles.

70. (canceled)

71. The method of claim 69, wherein the particle processing system is a microfluidic system.

72. The method of claim 69, wherein the functionalized portion is a tip of a biochemical actuator head included in the particle processing system.

73. (canceled)

74. The method of claim 69, wherein the functionalized portion is at least a portion of a channel included in the particle processing system and wherein the applying the first electric potential across the polymer facilitates binding of ligand-labeled particles flowing through the channel.

75. The method of claim 72, further comprising providing a particle flow through the channel, wherein the particle flow is fast enough to reduce, minimize or prevent non-ligand-labeled particles from binding or settling and slow enough to enable binding of ligand-labeled particles.

76.-79. (canceled)
